(19) United States
(12) Patent Application Publication
(10) Pub. No.: US 2007/0063219 A1
(43) Pub. Date: Mar. 22, 2007

(54) Voltage tunable integrated infrared imager

(75) Inventors: Amir Sa'ar, Mevaseret Zion (IL); Joseph Shappir, Mevasseret Zion (IL)

Correspondence Address: BROWDY AND NEIMARK, P.L.L.C.;624 NINTH STREET, NW, SUITE 300, WASHINGTON, DC, 20001-5303, US

(73) Assignee: Yissum Research Development Company of the Hebrew University of Jerusalem, Givat Ram (IL)

(21) Appl. No.: 10/554,113

(22) PCT Filed: Apr. 20, 2004
(86) PCT No.: PCT/IL04/00337

§ 371 Date: Aug. 21, 2006

(30) Foreign Application Priority Data
Apr. 21, 2003 (IL) 155536

(51) Int. Cl. H01L 31/00; H01L 21/00

(52) U.S. Cl. 257/189; 257/444; 438/48; 257/E31.064

(57) ABSTRACT

An integrated thermal imager for detecting combined passive LWIR or MWIR radiation of a scene and active SWIR radiation of a laser source is described The imager includes a two-dimensional focal plane array (2D-FPA) constituted by an assembly of voltage tunable photodetectors. Each voltage tunable photodetector integrates a quantum well infrared photodetector (QWIP) together with a heterojunction bipolar phototransistor (HBPT), thereby forming a pixel element in the 2D-FPA.

### FIELD OF THE INVENTION

This invention is generally in the field of infrared (IR) photodetectors, and relates to an integrated quantum well photo-detector that is capable of multicolor infrared detection.

### BACKGROUND OF THE INVENTION

Infrared detectors are used for collecting image information under conditions which do not allow regular optical observation, such as at night or through clouds, haze or dust. The information collected within infrared imaging can be enhanced if multiple bands (“colors”) of infrared radiation can be collected concurrently. Infrared radiation in different bands can be indicative of different elements in a scene, such as different materials, reflectivity, temperatures, etc. Therefore, for optimum viewing through use of infrared radiation, it is desired to have a sensor capable of concurrently detecting multiple bands of infrared radiation.

Multi-band infrared sensing has been performed with detectors of different types. The recent years have witnessed a tremendous progress in the development of quantum well infrared photodetectors (QWIPs) for thermal imaging of long wavelength infrared (LWIR) and middle wavelength infrared (MWIR) radiation (see, for example, U.S. Pat. No. 5,329,136 to Goossen; U.S. Pat. No. 5,646,421 to Liu; U.S. Pat. No. 6,060,704 to Hyun et al.; U.S. Pat. No. 6,445,000 to Masalkar et al.; U.S. Pat. Nos. 6,469,358 and 6,495,830 to Martin).

Conventional QWIP detectors are generally based on band-gap engineering of epitaxially grown heterostructures. The detection mechanism of the detectors involves absorption of IR photons due to optical transitions between quantized subbands of the quantum wells (QWs), which are constituted by an array of barrier and well layers.

Typically, when the semiconductor systems are grown on GaAs based substrates, the QWs are constituted of aluminum gallium arsenide AlGaAs barrier layers and appropriately doped gallium arsenide GaAs well layers (see, for example, H. C. Liu et al, Electron. Lett. 1999, V. 35, P. 2055). In turn, when the semiconductor systems are grown on a top of InP based substrates, the quantum well and barrier layers are made of InGaAsP or InGaAs and InP, respectfully (see, for example, S. D. Gunapala et al., Appl. Phys. Lett., 1992, V. 60, N. 5, P. 636-638).

The absorption process generates free carriers (electrons). The operation of the QWIP requires the application of a forward bias (e.g., several volts) across the QWIP, so that the excited carriers are swept toward the collector to give a photo-current response. As a result, it is possible to alter the center wavelength of the detector response in the range, 5-28 μm, by adjusting the QW width and/or the composition of the semiconductor alloy forming the QW barriers.

Furthermore, GaAs and/or InP based heterostructures are widely used to fabricate a variety of other electronic and optoelectronic devices, such as light emitting diodes (LEDs), a wide spectrum of transistors (such as metal-semiconductor field effect transistor (MESFET), heterojunction bipolar transistor (HBT), high electron mobility transistor (HEMT), modulation doped field effect transistor (MODFET), etc.), microwave integrated circuits (MMIC), etc (see, for example, S. R. Forrest, IEEE J. Quantum Electron., 1981, V. 17, N. 2, P. 217-226; R. F. Leheny et al, IEEE J. Quantum Electron., 1981, V. 17, N. 2, P. 227-231; R. F. Leheny et al, IEEE J. Quantum Electron., 1981, V. 17, N. 2, P. 232-238; N. Susa et al., IEEE J. Quantum Electron., 1981, V. 17, N. 2, P. 243-249; J. C. Campbell et al., IEEE J. Quantum Electron., 1981, V. 17, N. 2, P. 264-269).

In principle, each of these devices can monolithically be integrated with the QWIP to form an integrated device. This concept has been implemented recently in the development of integrated QWIP+LED (see, for example, U.S. Pat. No. 6,028,323 to Liu) and QWIP+pin photo-diode (see, for example, U.S. Pat. No. 6,060,704 to Hyun and article by H. Schneider et al., Appl. Phys. Lett., 1996, V. 68, P. 1832).

Some imaging applications require an imaging system capable of detecting passive LWIR and MWIR radiation concurrently with active short wavelength infrared (SWIR) radiation originated from lasers (e.g., a Nd:YAG and/or infrared diode lasers) enabling to operate in the wavelength band of 0.9-3 μm. Such an integrated system, usually referred to as a “see-spot IR imager”, is very important for many applications. In particular, lasers that enable to emit radiation at wavelengths of 0.98 μm, 1.06 μm, 1.3 μm and/or 1.55 μm are routinely used in such systems as range finders, target tracking and recognition, and others.

Conventional multi-band infrared sensing techniques based on a combination of several QWIPs are not adjustable to provide a simple and natural way to realize this function in focal plane arrays. On the other hand, the GaAs and InP QWIP integration technology may provide potential feasibility for fabricating a see-spot IR imager.

For example, a sensor assembly for imaging combined passive IR scenes and active laser radar (LADAR) scenes is described in U.S. Pat. No. 6,323,941 to Evans et al. The sensor assembly uses a dual-band IR semiconductor imager in the form of a semiconductor structure integrating two separate detectors connected in series. According to one embodiment, the passive detector, designed for a MWIR or LWIR absorbing region, comprises a QWIP having a stack of multiple quantum wells sandwiched between an array contact (arranged at one side of the structure) and an intermediate contact. The signal produced by the absorption of the MWIR or LWIR radiation is generated between these contacts. The active detector, designed for SWIR absorbing region, is formed of InGaAs region positioned between the intermediate contact and a contact at another side of the structure. A SWIR radiation signal is produced between these two contacts. The SWIR detector can form a photoconductor, a photodiode, or an avalanche photodiode. A second embodiment of the dual-band IR semiconductor imager uses a double stack for absorbing the SWIR and the MWIR or LWIR radiation, respectively. Both the stacks are formed to comprise p-n junctions. The sensor assembly developed in U.S. Pat. No. 6,323,941 employs special detector electronics capable to collect passive IR data and active LADAR data.

### SUMMARY OF THE INVENTION

There is a need in the art for, and it would be useful to have, a novel imaging technique for simultaneously detecting LWIR and MWIR radiation from thermal sources (passive imaging) along with the radiation from short wavelength IR lasers (active imaging).

The present invention satisfies the aforementioned need by providing an integrated imager for detecting combined passive and active radiation by a two-dimensional focal plane array (2D-FPA) connected to conventional readout electronic circuits for further image processing. According to the invention, the integrated imager includes a set of voltage tunable photodetectors, wherein each photodetector integrates a quantum well infrared photodetector (QWIP) together with a punch-through Heterojunction Bipolar Phototransistor (HBPT), thereby forming an element (pixel) in the 2D-FPA.

According to one embodiment of the invention, the QWIP includes a stack of epitaxial layers deposited on a substrate layer, while the HBPT includes another stack of epitaxial layers grown on the QWIP. The epitaxial layers include a first contact layer arranged underside of the QWIP layers and a second contact layer arranged at the upperside of the HBPT layers. The epitaxial layers include also a floating contact layer for providing a contact between said QWIP and said HBPT.

According to another embodiment of the invention, the HBPT includes a stack of epitaxial layers deposited on a substrate layer, and the QWIP includes another stack of epitaxial layers grown on said HBPT. In this case, the epitaxial layers include a first contact layer arranged underside of the HBPT layers, while a second contact layer is arranged at the upperside of the QWIP layers.

According to one example, the QWIP and HBPT layers can be composed of periodic GaAs/AlₓGa₁₋ₓAs and/or GaAs/InₓGa₁₋ₓAs multi-quantum well stacks, respectively, grown on a GaAs based substrate layer with the GaAs well width (depths) and Al and/or In compositions adjusted to yield the desired characteristics of the spectral band. According to another example, in order to yield the desired characteristics of the spectral band, the QWIP and HBPT layers can form a lattice composed of periodic InGaAs/InP and/or InGaAsP/InP multi-quantum well stacks matched to InP based substrates. Moreover, it should be understood that other semiconductor materials from among Groups II, III, IV and V from the periodic table can be used for the multi-quantum well layers grown on the substrate layer, e.g., compounds like AlGaAs/InGaAs, InP/InGaAs/InAlAs and/or InP/InGaP/InAlAs, etc.

According to the invention, the HBPT includes an emitter, a base arranged downstream of the emitter, multiple quantum well elements (wells and barriers) arranged downstream of the base and configured for absorbing the SWIR radiation, and a collector arranged downstream of the multiple quantum well elements. According to one example, the multiple quantum well elements can comprise GaAs based barrier and InGaAs based quantum wells layers. According to another example, the multiple quantum well elements can comprise InP barrier and In_{0.53}Ga_{0.47}As quantum wells layers. According to a further example, the multiple quantum well elements comprise InP barrier and In_{0.73}Ga_{0.27}As_{0.63}P_{0.37} quantum wells layers.

The emitter of the HBPT is constituted by at least one n-type epitaxial layer, the base is constituted by at least one p-type epitaxial layer, the multiple quantum well elements comprise a plurality of periodic layers of quantum wells/barrier layers, and the collector is constituted by at least one n-type epitaxial layer.

According to one example, the n-type epitaxial layer of the emitter can be an AlGaAs based layer. According to another example, the n-type epitaxial layer of the emitter can be an InP based layer.

In turn, according to one example, the p-type epitaxial layer of the base can be a GaAs based layer. According to another example, the p-type epitaxial layer of the base can be an In_{0.53}Ga_{0.47}As layer. According to a further example, the p-type epitaxial layer of the base can be an In_{0.73}Ga_{0.27}As_{0.63}P_{0.37} layer.

Likewise, according to one example, the n-type epitaxial layer of the collector can be a GaAs based layer. According to another example, the n-type epitaxial layer of the collector can be an In_{0.53}Ga_{0.47}As layer. According to a further example, the n-type epitaxial layer of the collector can be an In_{0.73}Ga_{0.27}As_{0.63}P_{0.37} layer.

Each voltage tunable photodetector of the 2D-FPA is adapted to sense the active SWIR radiation by means of the HBPT and the passive LWIR or MWIR radiation by means of the QWIP. When a first bias voltage is applied across the voltage tunable photodetector, the HBPT operates in the saturation mode. This operation mode of the voltage tunable photodetector is aimed at sensing SWIR radiation. When a second predetermined bias voltage having a magnitude higher than that of the first predetermined bias voltage) is applied across the photodetector, the HBPT operates in a punch-through breakdown mode. This is the normal operation mode of the voltage tunable photodetector where the change of QWIP photo-conductivity gives rise to the photo-current response.

The integrated imager according to the present invention is of durable and reliable construction, may be easily and efficiently manufactured and marketed, and may have low manufacturing cost.

Thus, in accordance with one broad aspect of the invention, there is provided an integrated imager for detecting combined passive LWIR or MWIR radiation of a scene and active SWIR radiation of a laser source, comprising a two-dimensional focal plane array (2D-FPA) constituted by an assembly of voltage tunable photodetectors, wherein each voltage tunable photodetector integrates a quantum well infrared photodetector (QWIP) together with a heterojunction bipolar phototransistor (HBPT), thereby forming a pixel element in the 2D-FPA.

In accordance with another broad aspect of the invention, there is provided a voltage tunable photodetector for sensing combined passive LWIR or MWIR radiation of a scene and active SWIR radiation of a laser source, comprising a quantum well infrared photodetector (QWIP) integrated together with a heterojunction bipolar phototransistor (HBPT).

In accordance with a still another broad aspect of the invention, there is provided a method of operating a integrated thermal imager for detecting combined passive LWIR or MWIR radiation of a scene and active SWIR radiation of a laser source, wherein said integrated thermal imager includes a two-dimensional focal plane array (2D-FPA) constituted by an assembly of voltage tunable photodetectors, wherein each voltage tunable photodetector integrates a quantum well infrared photodetector (QWIP) together with a heterojunction bipolar phototransistor (HBPT), thereby forming a pixel element in the 2D-FPA, the method comprising:
(a) obtaining said passive LWIR or MWIR radiation along with said active SWIR radiation, and converting the radiation into photo-current;
(b) applying a first predetermined bias voltage across said voltage tunable photodetector for sensing said active SWIR radiation by means of the HBPT,
(c) applying a second predetermined bias voltage across said voltage tunable photodetector for sensing said passive LWIR or MWIR radiation by means of the QWIP; and the scene and
(d) creating an image of at least a portion of the scene and the laser source.

There has thus been outlined, rather broadly, the more important features of the invention so that the detailed description thereof that follows hereinafter may be better understood. Additional details and advantages of the invention will be set forth in the detailed description, and in part will be appreciated from the description, or may be learned by practice of the invention.

### BRIEF DESCRIPTION OF THE DRAWINGS

In order to understand the invention and to see how it may be carried out in practice, a preferred embodiment will now be described, by way of non-limiting example only, with reference to the accompanying drawings, in which:

FIG. 1 illustrates a sectional view of a two-dimensional focal plane array (2D-FPA) of an integrated imager of the present invention;

FIG. 2 illustrates a schematic view of an example of a voltage tunable photodetector, according to the invention;

FIG. 3 is a schematic cross-sectional view of the voltage tunable photodetector according to one embodiment of the present invention, which shows a basic structure thereof;

FIG. 4 is a photoluminescence spectrum of the reference sample including five-period InGaAs quantum wells at 77K;

FIG. 5 illustrates a schematic view of an energy band edge profile of the HBT utilized in the voltage tunable photodetector of the present invention; and

FIG. 6 shows typical volt-ampere characteristics for positive (forward) bias voltages of the HBPT utilized in the voltage tunable photodetector of the present invention.

### DETAILED DESCRIPTION OF SPECIFIC EMBODIMENTS

The principles and operation of the waveguide structure according to the present invention may be better understood with reference to the drawings and the accompanying description, it being understood that these drawings and examples in the description are given for illustrative purposes only and are not meant to be limiting. Dimensions of layers and regions may be exaggerated for clarity. It should be noted that the blocks in the figures are intended as functional entities only, such that the functional relationships between the entities are shown, rather than any physical connections and/or physical relationships.

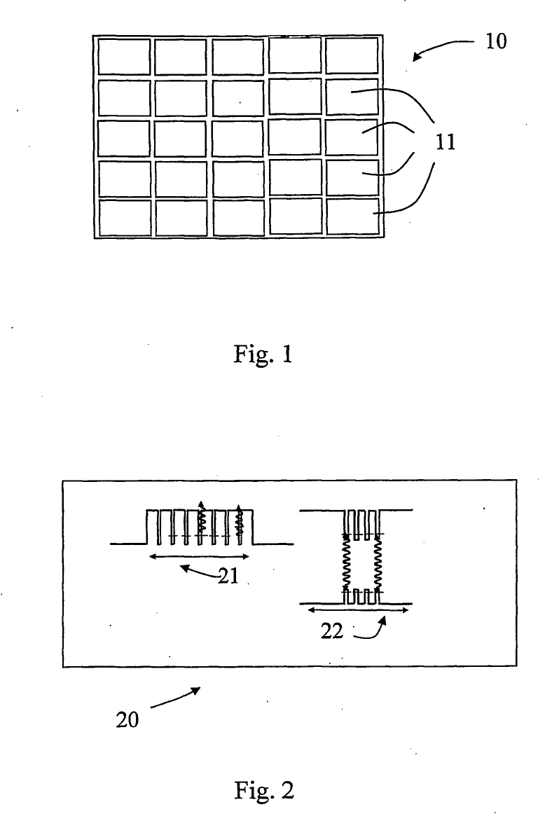

Referring to FIG. 1, there is schematically illustrated a two-dimensional focal plane array (2D-FPA) of an integrated see-spot imager 10 of the present invention constituted by an assembly of pixel elements 11. Each pixel element 11 of the 2D-FPA is based on a voltage tunable photodetector configured for obtaining passive LWIR or MWIR radiation of a scene and active SWIR radiation of a laser source, and converting the radiation into photo-current. Each voltage tunable photodetector is connected to a readout electronic circuit (not shown) adapted for reading the photo-current and performing image processing. The readout electronic circuit can, for example, be a standard readout electronic circuit usually employed in connection with IR detectors. The pixel elements 11 are replicated to produce a complete two-dimensional imager 10 of the desired size, such as 640 pixels by 480 pixels or other.

The integrated imager of the present invention can be operable in four different imaging modes. The first mode is referred to as a synchronized imaging mode, in which the active IR laser source (emitting, for example, short pulses of radiation at 0.98 μm, 1.06 μm, 1.3 μm, and/or 1.55 μm) provides a synchronization electronic signal to the imager. This synchronization signal can be utilized to switch the voltage tunable photodetectors at each pixel of the 2D-FPA for sensing the active IR image of the laser pulses. At the rest of the frame time (e.g., at the time period requiring for collection of the data from the pixels of the 2D-FPA) the photodetectors can be set for imaging the passive IR radiation.

The second mode of imaging is referred to as a non-synchronized imaging mode. At this mode, the active IR laser source does not provide a synchronization signal to the see-spot imager. In this case the voltage tunable photodetectors at each pixel of the 2D-FPA can be set for passive IR imaging of the LWIR and/or MWIR radiation for a short period of time needed to accumulate enough electrons in the integration capacitors of the readout electronics of the system (ROIC). At the rest of the frame time the voltage tunable photodetectors can be set for detecting the active IR laser pulses.

The third mode of imaging is related to an imaging of the pure active SWIR radiation of the IR laser pulses without a passive IR imaging of the LWIR and/or MWIR radiation. In this case the voltage tunable detectors are employed for only active SWIR detection, thereby the radiation originated from the IR laser source is sensed and used to form an image.

Finally, the forth mode of imaging is related to a pure passive IR imaging, in which the voltage tunable photodetectors are employed for detection of only the passive LWIR and/or MWIR radiation. It should be noted that this mode is the normal mode of regular QWIP imaging.

FIG. 2 illustrates a schematic view of an example of a voltage tunable photodetector 20, according to the invention. The voltage tunable photodetector 20 integrates a quantum well infrared photodetector (QWIP) 21 together with a heterojunction bipolar phototransistor (HBPT) 22. The QWIP 21 is configured for sensing passive LWIR or MWIR radiation of a scene, while the HBPT 22 is configured for sensing active SWIR radiation of a near-IR laser source. The LWIR and MWIR radiation of interest may, for example, be the atmospheric transmission bands of 8-12 μm and 3-5 μm, respectively. While, the SWIR radiation of interest is, for example, the radiation originated from a near-IR laser in the wavelength band of about 0.9-3 μm.

According to one example, the near-IR laser can be a Nd:YAG laser enabling to emit radiation at a wavelength of 1.06 μm. According to another example, the near-IR laser can be a diode laser operating in at least at one of the following bands 0.98 μm, 1.3 μm and 1.55 μm.

As will be explained in details below, the voltage tunable photodetector 20 is configured for sensing the passive radiation at the LWIR or MWIR atmospheric windows at a given bias voltage, and the SWIR laser radiation at another bias voltage applied across the photodetector 20.

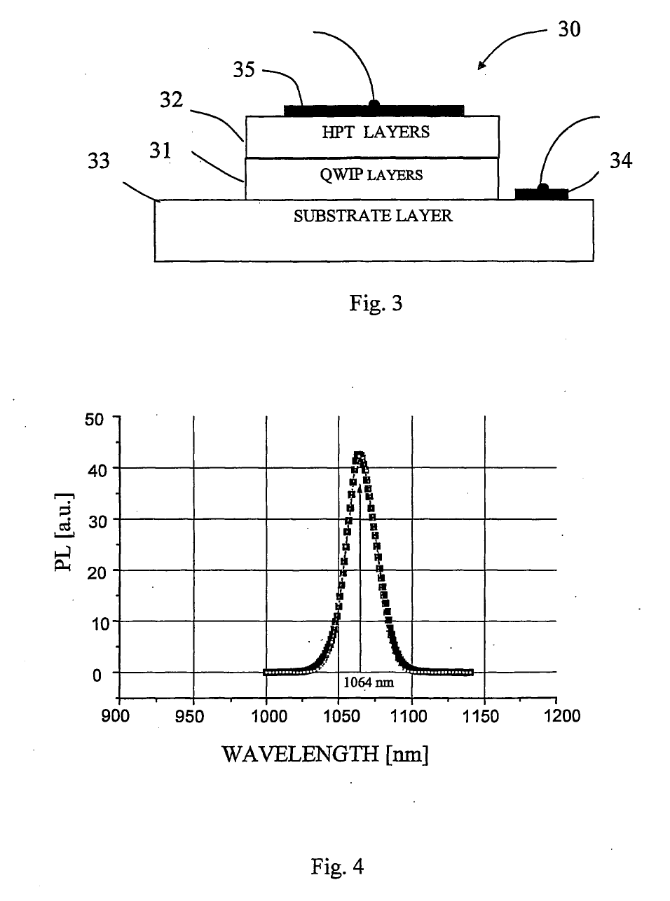

FIG. 3 shows a schematic cross-section view of a basic structure 30 of the voltage tunable photodetector (20 in FIG. 2), according to one embodiment of the present invention. The structure 30 includes two stacks of epitaxial layers 31 and 32 corresponding to the QWIP 21 and the HBPT 22, respectively. The QWIP layers 31 are deposited on a substrate layer 33 and the HBPT layers 32 are grown on top of the stack of the QWIP layers 31. All the layer sequences can be applied on top of each other, for example, with the aid of molecular beam epitaxy.

According to one preferable embodiment of the invention, the substrate layer 33 is mainly composed of GaAs. According to another preferable embodiment of the invention, the substrate layer 33 is mainly composed of InP. However, it should be understood that other materials (e.g., InAs, GaSb, Si, etc.) can also be used for the substrate layer 33.

It can be appreciated by a person versed in the art that inverted order of the stacks and/or layer sequences (not shown) are also feasible, in which first the HBPT layers are deposited on a substrate layer and then the QWIP layers are grown on top of the stack of the HBPT layers.

A first electrode 34 is formed in contact with a first contact layer (not shown here) arranged at the underside of the stack of the QWIP layers 31, and a second electrode 35 is formed in contact with a second contact layer (not shown here) arranged at the upperside of the stack of the HBPT layers 32. The first electrode 34 and the second electrode 35 can, for example be defined by a standard lithographic process. It should be noted that no electrode is formed between the stack of the QWIP layers 31 and the stack of the HBPT layers 32.

According to one example, the QWIP and HBPT layers 31 and 32 can be composed of periodic GaAs/AlₓGa₁₋ₓAs and/or GaAs/InₓGa₁₋ₓAs multi-quantum well stacks, respectively, grown on a GaAs based substrate layer with the GaAs well width (depths) and Al and/or In compositions adjusted to yield the desired characteristics of the spectral band.

According to another example, in order to yield the desired characteristics of the spectral band, the QWIP and HBPT layers 31 and 32 can form a lattice composed of periodic InGaAs/InP and/or InGaAsP/InP multi-quantum well stacks matched to InP substrates. In particular, In_{0.53}Ga_{0.47}As and In_{0.73}Ga_{0.27}As_{0.63}P_{0.37} layers grown on a InP based substrate layer can be used for the purpose of the invention.

Moreover, it should be understood that other compositions of InGaAs and InGaAsP with or without strain as well as other semiconductor materials selected from elements among Groups II, III, IV and V from the periodic table can be used for the multi-quantum well layers grown on the substrate layer 33, e.g., compounds like AlGaAs/InGaAs, InP/InGaAs/InAlAs and/or InP/InGaP/InAlAs, etc.

Table 1 illustrates one non-limiting example of the layout of the voltage tunable photodetector of the present invention, which details the device structure thereof.

TABLE 1

| | Repe- | Mole | Thick- | | |
|---|---|---|---|---|---|
| | tition | fraction | ness | | |
| | of the | (%) | of the | | Dopant |
| Layout | layer | of x- | layer | | Density |
| profile | (times) | component | (A) | Dopant | (cm⁻³) |
| n GaAs | 1 | | 6700 | Si | 5 × 10¹⁷ |
| n AlₓGa₁₋ₓAs | 1 | 24.2 | 300 | Si | 5 × 10¹⁷ |
| n GaAs | 1 | | 2000 | Si | 5 × 10¹⁷ |
| i GaAs | 1 | | 200 | None | |
| i INₓGa₁₋ₓAs | 5 | 35 | 57 | None | |
| i GaAs | | | 200 | None | |
| p GaAs | 1 | | 1720 | Be | 4 × 10¹⁶ |
| n AlₓGa₁₋ₓAs | 1 | 24.2 | 2000 | Si | 4 × 10¹⁶ |
| n AlₓGa₁₋ₓAs | 1 | 24.2 | 1000 | Si | 5 × 10¹⁷ |
| n GaAs | 1 | | 5000 | Si | 5 × 10¹⁷ |
| i AlₓGa₁₋ₓAs | 50 | 24.2 | 550 | None | |
| n GaAs | | | 51.5 | Si | 5 × 10¹⁷ |
| i AlₓGa₁₋ₓAs | 1 | 24.2 | 550 | None | |
| n GaAs | 1 | | 9000 | Si | 5 × 10¹⁷ |
| i AlₓGa₁₋ₓAs | 1 | 24.2 | 500 | None | |
| S.I. GaAs | 1 | | 625 × 10⁴ | | |
| Substrate | | | | | |
| layer | | | | | |

Referring to FIG. 3 and Table 1 together, the structure of the voltage tunable photodetector includes a semi-insulator (S.I.) GaAs substrate layer (the bottom row in Table 1), the stack of the QWIP layers 31 (represented by next six rows from the bottom to top in Table 1) formed on the substrate layer, and the stack of the HBPT layers 32 (represented by next nine rows from the bottom to top) formed upon the QWIP layers 31.

The stack of QWIP layers 31 includes an i-AlGaAs buffer layer (the 2-nd row from the bottom) grown on the substrate layer followed by the first contact n-type GaAs layer (the 3-rd row from the bottom). It should be noted that the first contact layer is formed in contact with the first electrode 34. Next, a AlGaAs barriers layer (the 4-th row) is grown on the first contact layer, followed by 50-period GaAs/AlGaAs multiple quantum wells/barriers (represented by 5-th and 6-th rows) adjusted for absorbing LWIR or MWIR radiation. An intermediate contact n-type GaAs layer is then formed upon the QWs layer (the 7-th row from the bottom). The intermediate contact layer serves as a floating electrode arranged for providing a contact between the QWIP and HBPT.

The stack of the HBPT layers 32 includes two n-type AlGaAs layers (represented by the 8-th and 9-th rows from the bottom) forming the emitter of the HBPT (22 in FIG. 2). Further, the stack of the HBPT layers 32 includes a p-type GaAs layer (the 10-th row) forming the p-type base of the HBPT. The doping level of the p-type base is chosen to allow a punch-through breakdown through the HBPT when a desired bias voltage is applied thereacross. It should be noted that in this particular example, the breakdown voltage is about 1 Volt. Next five-period GaAs/InGaAs multiple quantum elements (wells/barriers) followed by a GaAs layer are formed on the p-type base, which configured for absorbing the SWIR laser light (the 11-th, 12-th and 13-th rows). Further, an n-type GaAs layers (the 14th row from the bottom) is grown on the QW layers, forming the collector of the heterostructure n-p-n bipolar phototransistor. Finally, the stack of the HBPT layers 32 includes the second contact layer, being a bi-layer, that is formed on the collector from the n-type AlGaAs and GaAs layers (the 15-th and 16-th rows from the bottom). It should be noted that the second contact layer is formed in contact with the second electrode 35.

A reference sample including five-period InGaAs quantum wells was grown and tested. In particular, it was found that the quantum wells with 35% In concentration and having a width of 57A can be used for resonant absorption at 1.06 μm. A photoluminescence (PL) spectrum of the reference sample at the temperature of 77K is shown in FIG. 4. As can be seen, the maximum of the PL spectrum lies at the wavelength of 1064 nm with a full width at half maximum (FWHM) of 25 nm. This test demonstrates the usability of the InGaAs quantum wells for detection of SWIR radiation. It should be noted that other concentrations of In, in the range of about 20%-35% (with wider quantum wells) can also be used for resonance absorption at 1.06 μm.

Another example of the structure of the voltage photodetector will be generally described herein below. According to this example, the QWIP and the HBPT layers 31 and 32 are grown on the substrate layer 33 made of InP.

In particular, the stack of the QWIP layers 31 can include n-doped In_{0.53}Ga_{0.47}As layers of the quantum well and undoped InP barrier layers of the barrier material. It should be noted that In_{0.73}Ga_{0.27}As_{0.63}P_{0.37} layers can also be used as the quantum well material. The width of the quantum well material (e.g., In_{0.53}Ga_{0.47}As or In_{0.73}Ga_{0.27}As_{0.63}P_{0.37}) can be adjusted to absorb the desired LWIR or MWIR radiation.

In turn, the stack of the HBPT layers can include: an emitter having at least one n-doped InP layer, a base having at least one p-doped layer made of either In_{0.53}Ga_{0.47}As or In_{0.73}Ga_{0.27}As_{0.63}P_{0.37} material, and a collector made of at least one layer made of either n-doped In_{0.53}Ga_{0.47}As or In_{0.73}Ga_{0.27}As_{0.63}P_{0.37} material.

According to one embodiment of this example, the elements for absorbing the SWIR radiation can be either the p-doped In_{0.53}Ga_{0.47}As layers or In_{0.73}Ga_{0.27}As_{0.63}P_{0.37} layers of the base. According to another embodiment of this example, the SWIR absorbing elements can be either the In_{0.53}Ga_{0.47}As/InP quantum wells or In_{0.73}Ga_{0.27}As_{0.63}P_{0.37}/InP quantum wells of the collector.

The operation of the QWIP utilized in the voltage tunable photodetector of the present invention is known per se, and therefore will not be expounded further herein. As for the operation of the HBPT utilized in the voltage tunable photodetector, it will be explained hereinbelow.

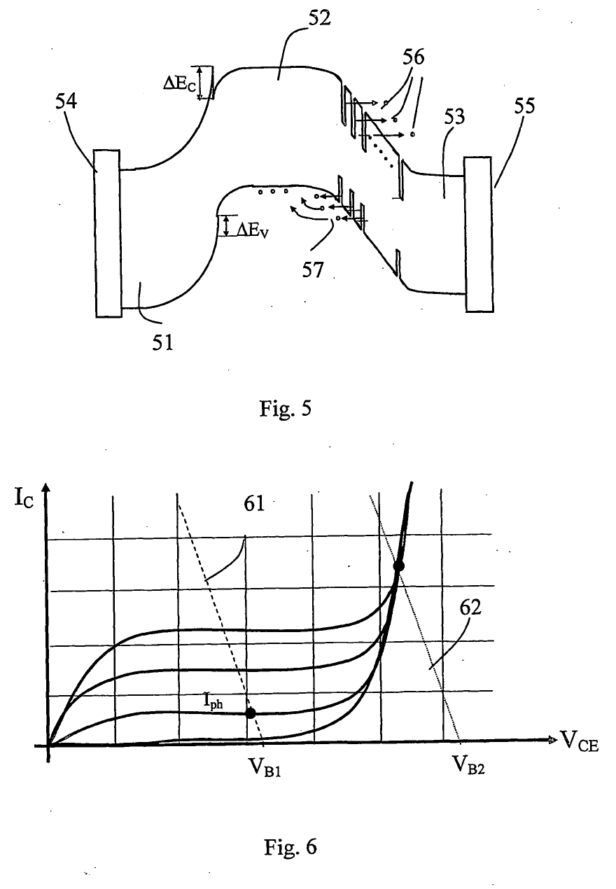

Referring to FIG. 5, a schematic view of an energy band edge profile of the HBPT utilized in the voltage tunable photodetector of the invention is illustrated. It can be appreciated that the HBPT is an n-p-n Heterojunction Bipolar Transistor including an emitter 51, a narrow base 52 and a collector 53.

The emitter 51 can be made of n-type AlGaAs for GaAs substrates. Likewise, the emitter 51 can be made of n-type InP for InP substrates. In turn, the base 52 can be made of p-type GaAs for GaAs substrates. Likewise, the base 52 can be made of p-type In_{0.53}Ga_{0.47}As or In_{0.73}Ga_{0.27}As_{0.63}P_{0.37} for InP substrates. A region of the collector 53 can be composed of a nominally intrinsic InGaAs/GaAs quantum wells region followed by a heavily doped n-type GaAs sub-collector region for the case when the photodetector is built on a GaAs substrate. Likewise, the region of the collector 53 can be an In_{0.53}Ga_{0.47}As or In_{0.73}Ga_{0.27}As_{0.63}P_{0.37} region followed by a heavily doped In_{0.53}Ga_{0.47}As or In_{0.73}Ga_{0.27}As_{0.63}P_{0.37} sub-collector region when the photodetector is built on an InP substrate.

The HBPT operates in the floating base configuration in which only two contacts via the electrodes 54 and 55 are arranged to the emitter and collector, correspondingly. Under normal operating conditions, a voltage V_{CE} is applied between the emitter and the collector. In the dark, since the collector-base junction is under reverse bias, there is no current flow in the device (except for the dark current of the junction that is very low). For example, a typical resistance of the device (under the appropriate design of the doping levels) is more than 100 Mohm for a detector having the size of 50×50 μm².

Under a resonant illumination (e.g., the illumination at 0.98 μm, 1.06 μm, 1.3 μm and/or 1.55 μm), electron-hole pairs can be generated via strong excitonic absorption in the InGaAs quantum wells built on GaAs and/or InP substrates.

Likewise, electron-hole pairs can be generated via strong excitonic absorption in the In_{0.53}Ga_{0.47}As or In_{0.73}Ga_{0.27}As_{0.63}P_{0.37} base built on an InP substrate.

The electrons 56 escape into the collector side via tunneling under the strong electric field across the collector-base junction (when the photodetector is built on a GaAs substrate) and/or via diffusion (when the photodetector is built on an InP based substrate). However, the holes 57 that tunnel into the base are efficiently trapped in the base due to the heterojunction structure at the emitter-base junction (i.e., the existence of an energy barrier, ΔEᵥ, in the emitter-base junction). The holes 57, in turn, charge the base and activate the normal gain mechanism of the bipolar transistor (i.e., the current of the photo-generated holes replace the base current which takes place in ordinary bipolar transistors).

The dual detection mechanism of the integrated (HBPT+QWIP) voltage tunable photodetector will be explained now hereinbelow.

FIG. 6 shows typical collector current versus collector-emitter voltage (V_{CE}) characteristics of the HBPT at various photo-currents (Iₚₕ) for positive (forward) bias voltages. It should be noted that Iₚₕ replaces the base current in ordinary heterojunction bipolar transistors.

In operation, when a first bias voltage V_{B1} is applied across the voltage tunable photodetector, the HBPT operates in the saturation mode with a very large differential resistance, typically, of the order of 100 Mohm. Therefore, since the resistance of the QWIP in this case (e.g., at the temperature of 77K) can be of the order of 0.1 Mohm, all the bias voltage drops across the HBPT and the QWIP does not function in this bias. In this case, Iₚₕ represents the base current that is generated by the HBPT owing to the SWIR radiation. Hence, this operation mode of the voltage tunable photodetector is aimed at sensing SWIR radiation. The computer simulations carried out for the HBPT demonstrated that a typical gain of the phototransistor in this operation mode can be of the order of 10-500. The dashed line 61 in FIG. 6 represents the load line of the voltage tunable photodetector for this operation.

On the other hand, when a second biased voltage V_{B2} is applied across the integrated voltage tunable photodetector of the invention, the HBPT operates in the breakdown mode. In this case, the phototransistor behaves as a current source with a differential resistance much smaller than that of the QWIP. Hence, when the bias voltage has a magnitude that is above the breakdown voltage of the HBPT, all the bias voltage drops across the QWIP. This is the normal operation mode of the voltage tunable photodetector where the change of QWIP photo-conductivity (due to the LWIR or MWIR illumination) gives rise to a photo-current response. The load line corresponding to this mode of operation is represented by the dotted line (62 in FIG. 6).

As can be appreciated by a person versed in the art, generally there are two breakdown modes of operation of the HBPT at the bias voltage of V_{B2}, such as the avalanche breakdown and the punch-through breakdown mode (see, for example, Y. Wang et al, 1993, J. Appl. Phys. V. 74, P. 6978). It should be noted, however, that the operation of bipolar transistors in the ordinary mode of avalanche breakdown is not recommended due to, inter alia, the following reasons:

(i) Typical breakdown voltages are fairly high and usually cannot be controlled to a specific value as required for the purposes of the present invention;

(ii) Due to the imperfections, unintentional impurities and defects of the structure of the HBPT, the breakdown voltage can vary from one HBPT to the other;

(iii) The recovery time from the avalanche breakdown is usually long (up to a few milliseconds), that would impose a strong limitation on the switching and the integration time of the signals.

For all the above reasons, preferably to operate the HBPT in the punch-through breakdown mode. In this case, the breakdown is achieved by depletion of carriers from the transistor base up to a level where a short-cut between the emitter and the collector is formed. The advantages of this breakdown mode are, inter alia, as follows: First, the punch-through breakdown voltage can be easily tuned to a desired value (for example, by controlling the doping level and the thickness of the base). Second, the punch-through breakdown voltage is insensitive to the level of unintentional impurities and the time response is expected to be very fast (at least less than a microsecond).

As such, those skilled in the art to which the present invention pertains, can appreciate that while the present invention has been described in terms of preferred embodiments, the concept upon which this disclosure is based may readily be utilized as a basis for the designing of other structures, systems and processes for carrying out the several purposes of the present invention.

For example, a diffraction grating usually employed in connection with QWIPs can also be applied onto or under the structure of the voltage tunable photodetector of the present invention.

In the method claims that follow, alphabetic characters used to designate claim steps are provided for convenience only and do not imply any particular order of performing the steps.

Also, it is to be understood that the phraseology and terminology employed herein are for the purpose of description and should not be regarded as limiting.

Finally, it should be noted that the word “comprising” as used throughout the appended claims is to be interpreted to mean “including but not limited to”.

It is important, therefore, that the scope of the invention is not construed as being limited by the illustrative embodiments set forth herein. Other variations are possible within the scope of the present invention as defined in the appended claims and their equivalents.

1-60. (canceled)

61. A voltage tunable photodetector for sensing combined passive LWIR or MWIR radiation of a scene and active SWIR radiation of a laser source, comprising a quantum well infrared photodetector (QWIP) integrated together with a heterojunction bipolar phototransistor (HBPT).

62. The voltage tunable photodetector of claim 61 wherein said active SWIR radiation is sensed by means of the HBPT, when a first predetermined bias voltage is applied across said voltage tunable photodetector, and said passive LWIR or MWIR radiation is sensed by means of the QWIP, when a second predetermined bias voltage is applied across said voltage tunable photodetector.

63. The voltage tunable photodetector of claim 61 wherein the QWIP includes a stack of epitaxial layers deposited on a substrate layer and the HBPT includes another stack of epitaxial layers grown on said QWIP.

64. The voltage tunable photodetector of claim 63 wherein said substrate layer is made of a material selected from GaAs and InP.

65. The voltage tunable photodetector of claim 63 wherein the epitaxial layers include a first contact layer arranged underside of the QWIP layers and a second contact layer arranged at the upperside of the HBPT layers.

66. The voltage tunable photodetector of claim 65 wherein the epitaxial layers include a floating contact layer for providing a contact between said QWIP and said HBPT.

67. The voltage tunable photodetector of claim 61 wherein the HBPT includes a stack of epitaxial layers deposited on a substrate layer and the QWIP includes another stack of epitaxial layers grown on said HBPT.

68. The voltage tunable photodetector of claim 67 wherein said substrate layer is made of a material selected from GaAs and InP.

69. The voltage tunable photodetector of claim 67 wherein the epitaxial layers include a first contact layer arranged underside of the HBPT layers and a second contact layer arranged at the upperside of the QWIP layers.

70. The voltage tunable photodetector of claim 69 wherein the epitaxial layers include a floating contact layer for providing a contact between said QWIP and said HBPT.

71. The voltage tunable photodetector of claim 64 wherein said QWIP includes GaAs based quantum wells and AlGaAs based barrier layers.

72. The voltage tunable photodetector of claim 64 wherein said QWIP includes In_{0.53}Ga_{0.47}As quantum wells and InP based barrier layers.

73. The voltage tunable photodetector of claim 64 wherein said QWIP includes In_{0.73}Ga_{0.27}As_{0.63}P_{0.37} quantum wells and InP based barrier layers.

74. The voltage tunable photodetector of claim 61 wherein said HBPT includes:
an emitter constituted by at least one n-type epitaxial layer;
a base arranged downstream of said emitter and constituted by at least one p-type epitaxial layer;
multiple quantum well elements arranged downstream of said base and configured for absorbing the SWIR radiation; and
a collector arranged downstream of said multiple quantum well elements and constituted by at least one n-type epitaxial layer.

75. The voltage tunable photodetector of claim 74 wherein said at least one n-type epitaxial layer of the emitter is a layer based on at least one element selected from the group including AlGaAs and InP.

76. The voltage tunable photodetector of claim 74 wherein said at least one p-type epitaxial layer of the base is a layer based on at least one element selected from the group including GaAs, In_{0.53}Ga_{0.47}As and In_{0.73}Ga_{0.27}As_{0.63}P_{0.37}.

77. The voltage tunable photodetector of claim 74 wherein said multiple quantum well elements comprise GaAs based barrier and InGaAs based quantum wells layers.

78. The voltage tunable photodetector of claim 74 wherein said multiple quantum well elements comprise InP barrier and In_{0.53}Ga_{0.47}As quantum wells layers.

79. The voltage tunable photodetector of claim 74 wherein said multiple quantum well elements comprise InP barrier and In_{0.73}Ga_{0.27}As_{0.63}P_{0.37} quantum wells layers.

80. The voltage tunable photodetector of claim 74 wherein said at least one n-type epitaxial layer of the collector is a layer based on at least one element selected from the group including GaAs, In_{0.53}Ga_{0.47}As and In_{0.73}Ga_{0.27}As_{0.63}P_{0.37}.

81. The voltage tunable photodetector of claim 74 wherein the HBPT is being operated in a floating base mode.

82. An integrated thermal imager for detecting combined passive LWIR or MWIR radiation of a scene and active SWIR radiation of a laser source, comprising a two-dimensional focal plane array (2D-FPA) constituted by an assembly of voltage tunable photodetectors,
wherein each voltage tunable photodetector integrates a quantum well infrared photodetector (QWIP) together with a heterojunction bipolar phototransistor (HBPT), thereby forming a pixel element in the 2D-FPA.

83. A method of operating a integrated thermal imager for detecting combined passive LWIR or MWIR radiation of a scene and active SWIR radiation of a laser source, wherein said integrated thermal imager includes a two-dimensional focal plane array (2D-FPA) constituted by an assembly of voltage tunable photodetectors, wherein each voltage tunable photodetector integrates a quantum well infrared photodetector (QWIP) together with a heterojunction bipolar phototransistor (HBPT), thereby forming a pixel element in the 2D-FPA, the method comprising:
(a) obtaining said passive LWIR or MWIR radiation along with said active SWIR radiation, and converting the radiation into photo-current;
(b) applying a first predetermined bias voltage across said voltage tunable photodetector for sensing said active SWIR radiation by means of the HBPT,
(c) applying a second predetermined bias voltage across said voltage tunable photodetector for sensing said passive LWIR or MWIR radiation by means of the QWIP; and the scene and
(d) creating an image of at least a portion of the scene and the laser source.

84. The method of claim 83 wherein said integrated thermal imager being operable in at least one imaging mode selected from a synchronized imaging mode, a non-synchronized imaging mode, an imaging of the pure active SWIR radiation and an imaging of the pure passive LWIR or MWIR radiation.
